(19) United States
(12) Patent Application Publication
(10) Pub. No.: US 2025/0336791 A1
(43) Pub. Date: Oct. 30, 2025

(54) PACKAGE STRUCTURE AND MANUFACTURING METHOD THEREOF

(71) Applicant: Taiwan Semiconductor Manufacturing Company, Ltd., Hsinchu (TW)

(72) Inventors: Hsuan-Ting Kuo, Taichung City (TW); Hsiu-Jen Lin, Hsinchu County (TW); Ching-Hua Hsieh, Hsinchu (TW)

(73) Assignee: Taiwan Semiconductor Manufacturing Company, Ltd., Hsinchu (TW)

(21) Appl. No.: 18/646,723

(22) Filed: Apr. 25, 2024

(51) Int. Cl. H01L 23/498; H01L 21/48; H01L 21/56; H01L 23/00; H01L 23/31; H01L 23/522; H01L 25/18

(52) U.S. Cl. CPC H01L 23/49838; H01L 21/4853; H01L 21/56; H01L 23/31; H01L 23/49833; H01L 23/5223; H01L 24/08; H01L 24/14; H01L 24/16; H01L 24/32; H01L 24/73; H01L 25/18; H01L 2224/08225; H01L 2224/14051; H01L 2224/16225; H01L 2224/16245; H01L 2224/32145; H01L 2224/32225; H01L 2224/73204; H01L 2924/1431; H01L 2924/1436

(57) ABSTRACT

A package structure and a manufacturing method of a package structure are provided. The package structure includes a substrate, a first interposer, a second interposer, a first semiconductor die, a second semiconductor die and a flexible interconnect structure. The first interposer is bonded to the substrate. The second interposer is bonded to the substrate and spaced apart from the first interposer. The first semiconductor die is bonded to the first interposer. The second semiconductor die is bonded to the second interposer. The flexible interconnect structure is bonded to the first interposer and the second interposer.

### BACKGROUND

Bottom side high density interconnect methods keep developing larger area and finer pitch to further increase the overall interconnect density. However, as the overall interconnect density continuously increases, the methods encounter narrower process window and higher process cost with limited performance progress.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic top view of a package structure according to some embodiments of the present disclosure.

FIG. 2 is a schematic sectional view taken along line I-I′ in FIG. 1.

FIG. 3 and FIG. 4 are two schematic sectional views illustrating two examples of a flexible interconnect structure in FIG. 2.

FIG. 5 is a schematic top view of a package structure according to some embodiments of the present disclosure.

FIG. 6 is a schematic top view of a package structure according to some embodiments of the present disclosure.

FIG. 7 is a schematic sectional view of a package structure according to some embodiments of the present disclosure.

FIG. 8 is a schematic sectional view of a package structure according to some embodiments of the present disclosure.

FIG. 9 is a schematic top view of a package structure according to some embodiments of the present disclosure.

FIG. 10 is a schematic top view of a package structure according to some embodiments of the present disclosure.

FIG. 11 is a schematic sectional view taken along line II-II′ in FIG. 10.

FIG. 12 is a schematic top view of a package structure according to some embodiments of the present disclosure.

FIG. 13, FIG. 14 and FIG. 15 are schematic sectional views illustrating a manufacturing method of a package structure according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The conventional high density interconnect methods use local Si interconnect (LSI) bridge dies beneath semiconductor dies to increase the overall interconnect density. For example, the interconnect bridge dies are embedded in interposers or package substrates for interconnection between adjacent semiconductor dies and/or for smaller I/O pad pitches, smaller redistribution layer line width and/or the line space. However, the space or area beneath the semiconductor dies is limited, and the reduction in size and/or pitch of conductive features (e.g., wires and/or pads) also has its limitations. With the increasing need for higher 3D interconnect density and/or larger capacitance, the conventional high density interconnect methods encounter narrower process window and higher process cost with limited performance progress.

In the present disclosure, a flexible interconnect structure is applied between or above adjacent elements (e.g., adjacent packages or adjacent semiconductor dies) to be interconnected to increase the degree of freedom of interconnection, improve the bonding between the interconnect structure and the adjacent elements with different heights/levels, and/or increase the yield. The bridge dies in the flexible interconnect structure can include high capacitance (e.g., each of the bridge dies includes an embedded deep trench capacitor) to filter the ripple in the circuit, thereby reducing signal distortion. The flexible interconnect structure can be bonded to the adjacent elements through an active alignment assembly process, during which electrical signals are provided while simultaneously measuring the output signal repeatedly to confirm whether there is electrical conduction between the flexible interconnect structure and the bonded elements, thereby whether the flexible interconnect structure and the adjacent elements are well bonded can be confirmed in time, and repairs can be made immediately if the bond is poor.

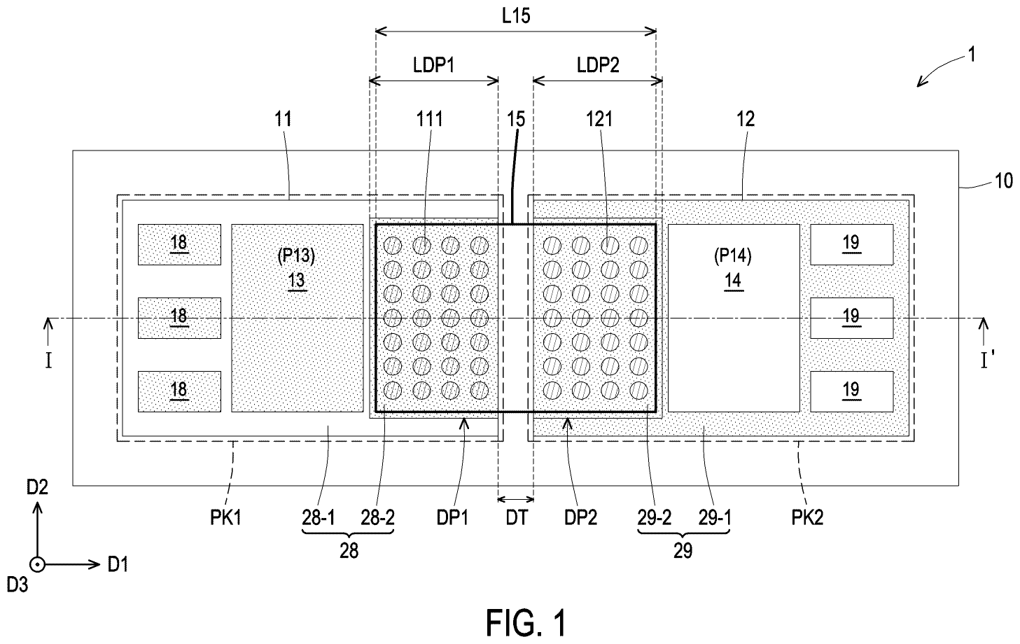

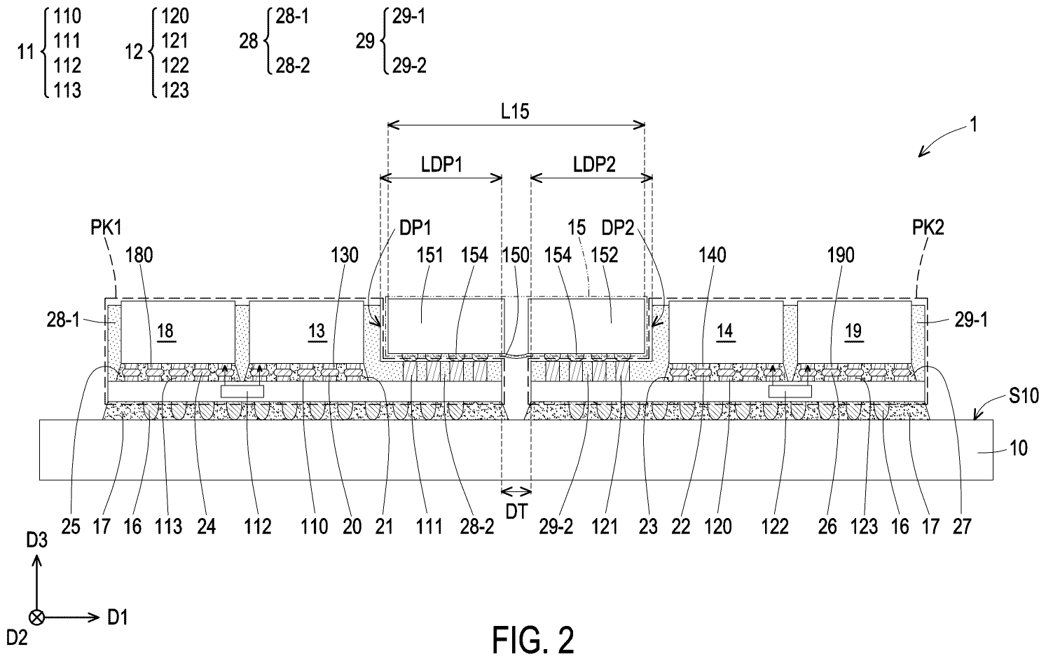

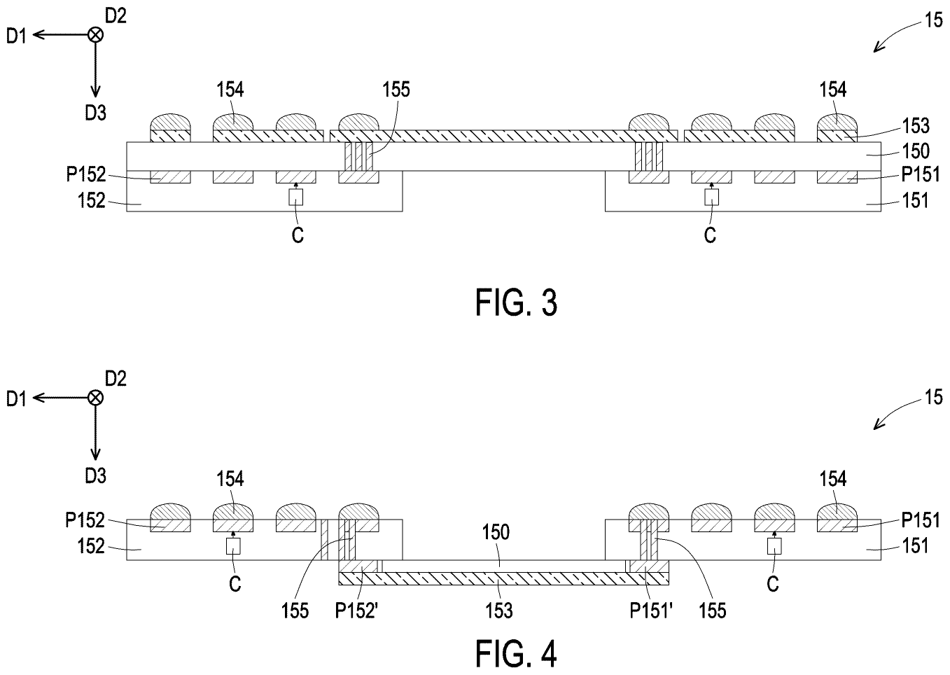

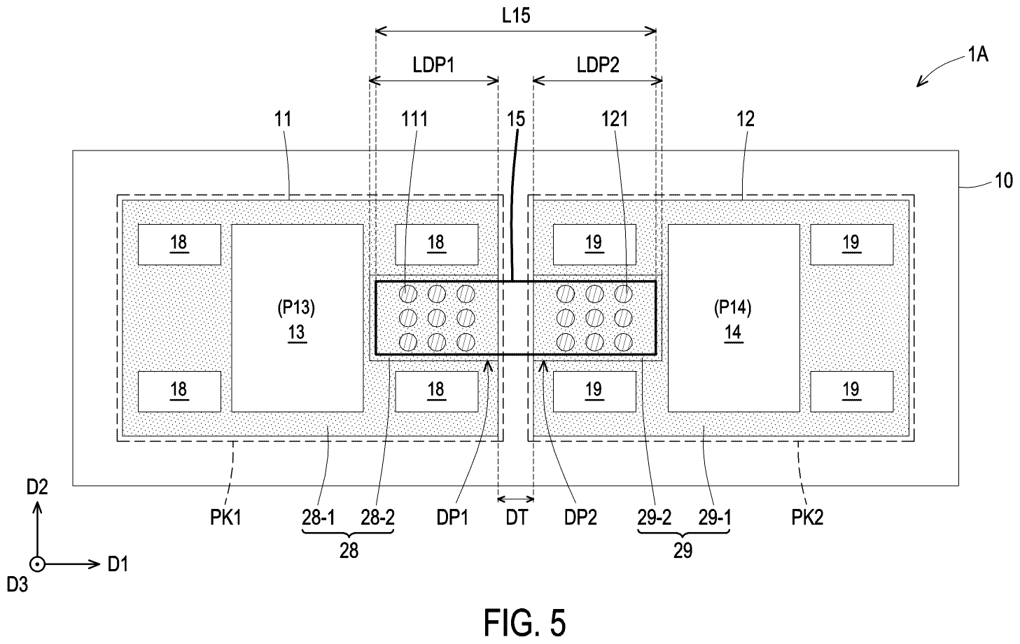

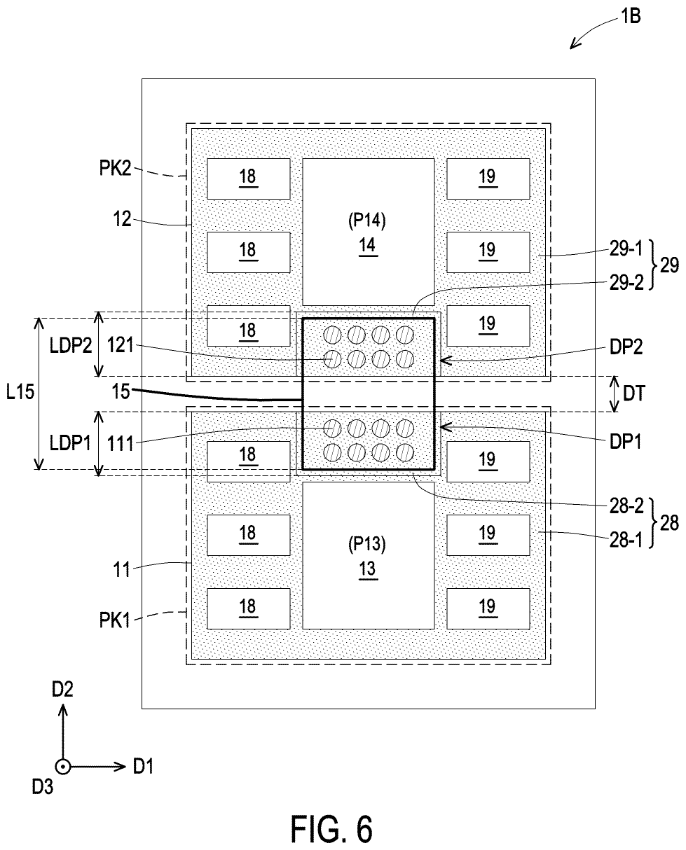

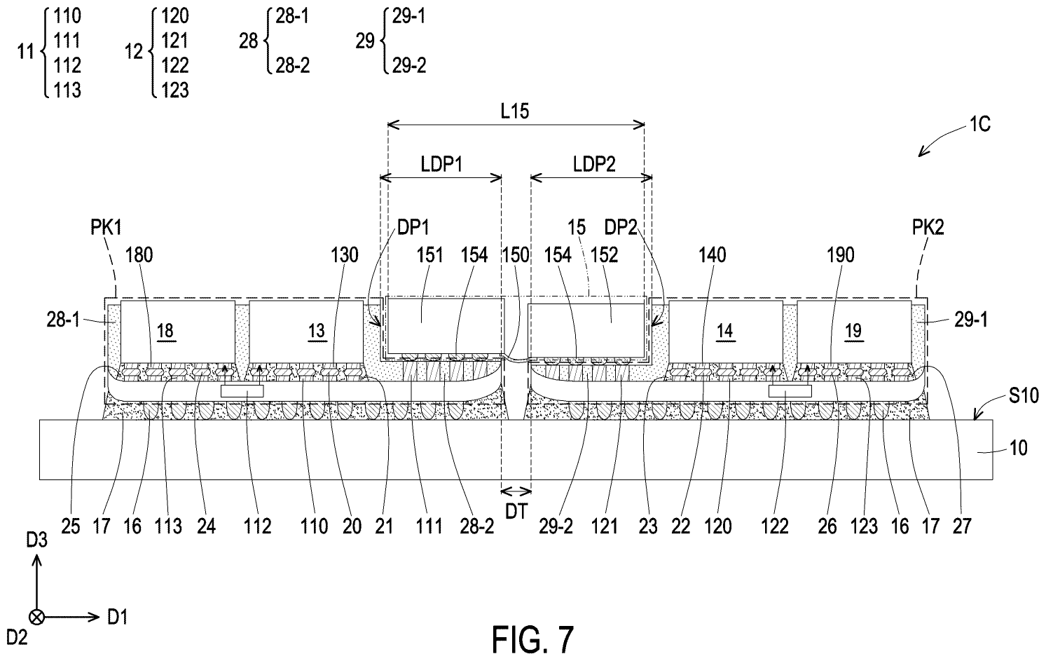

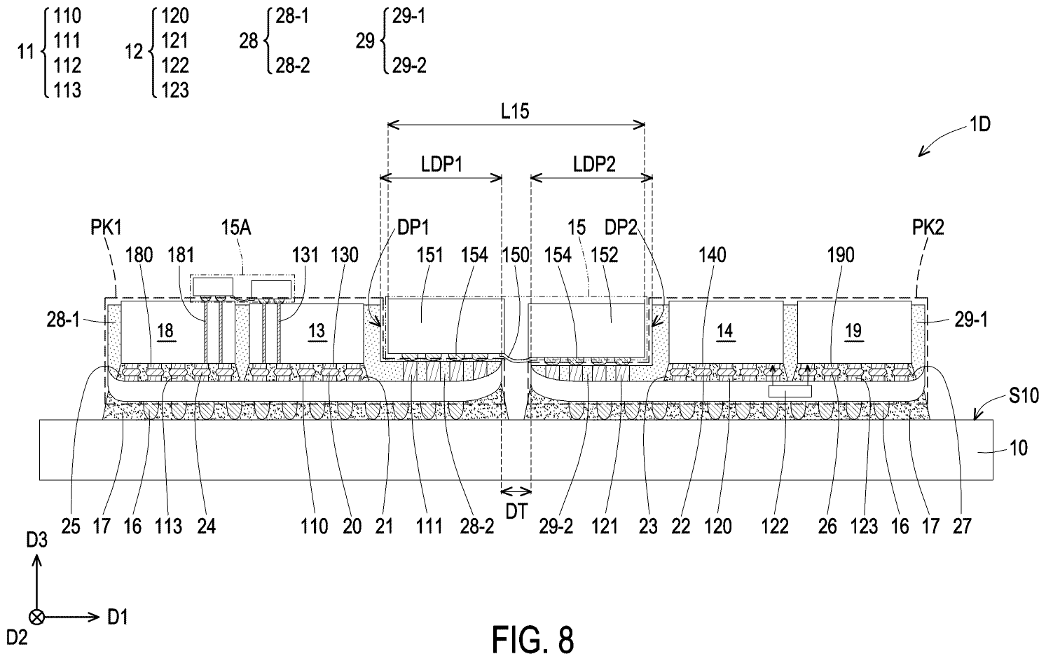

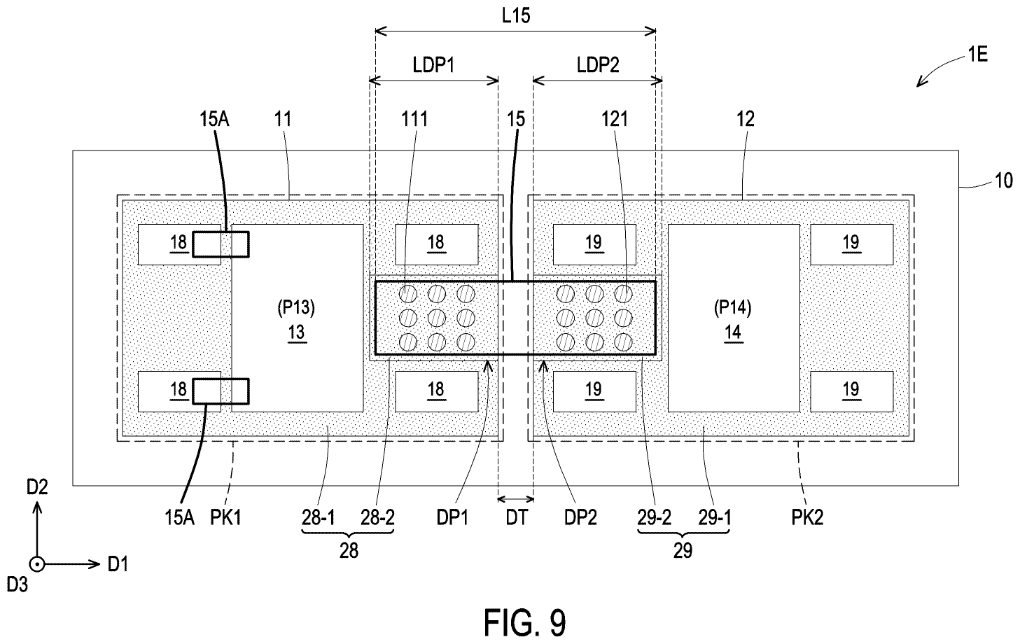

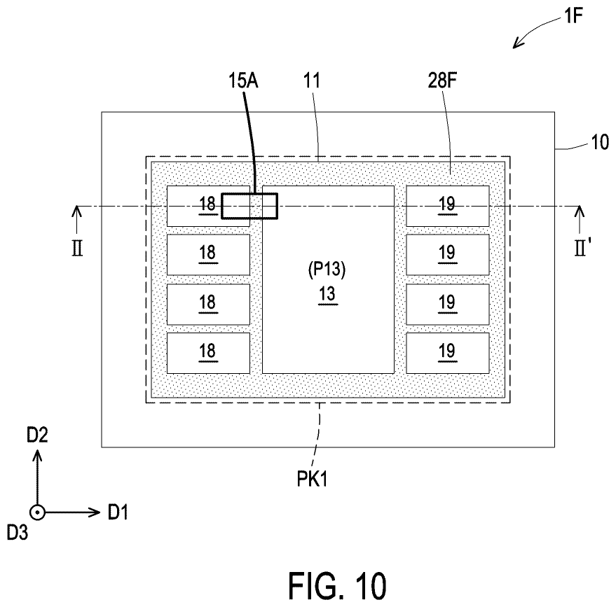

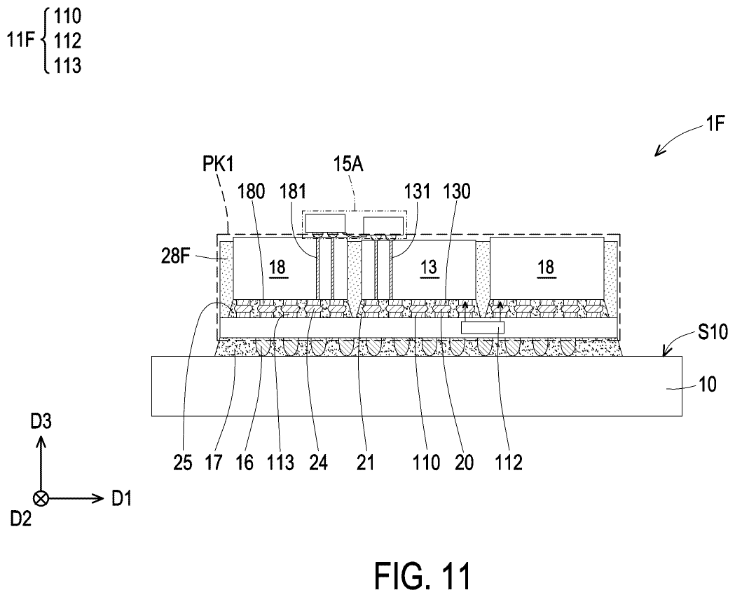

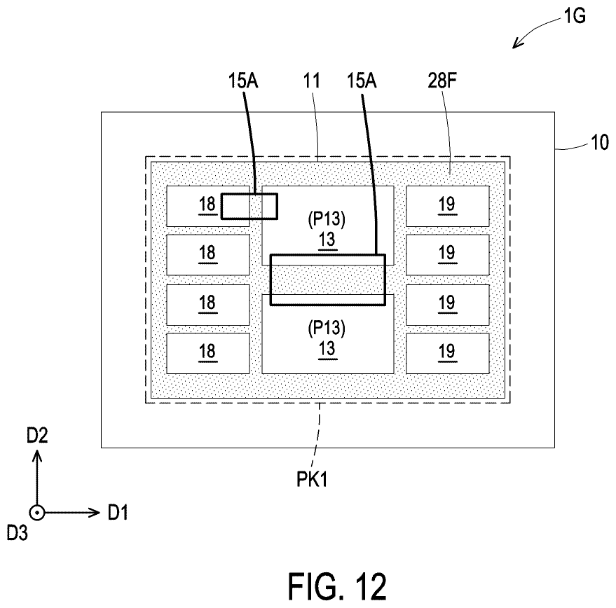

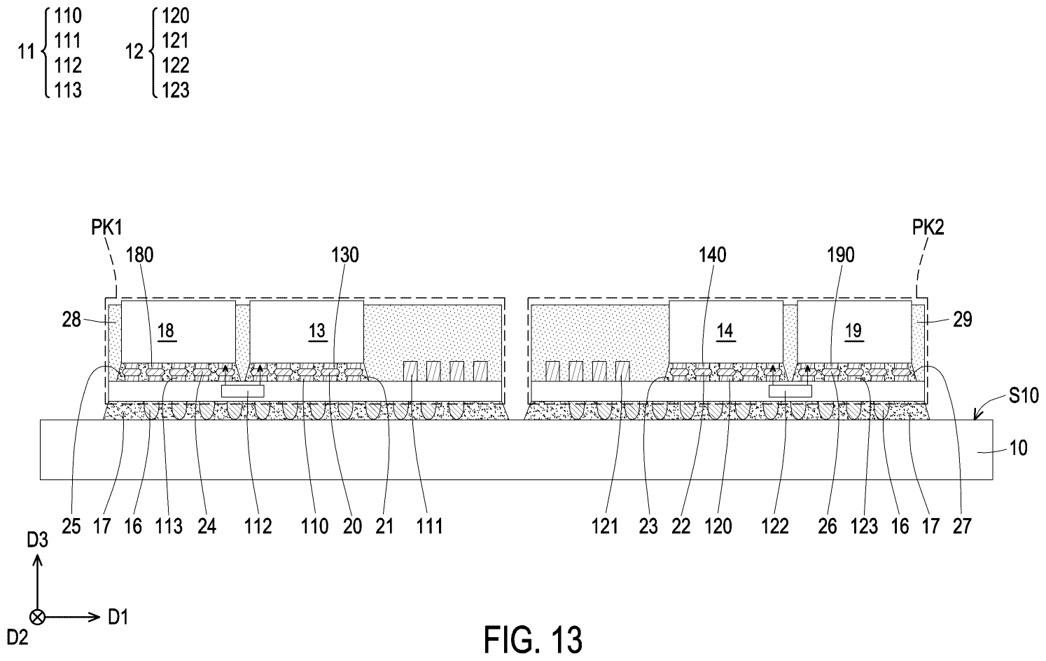

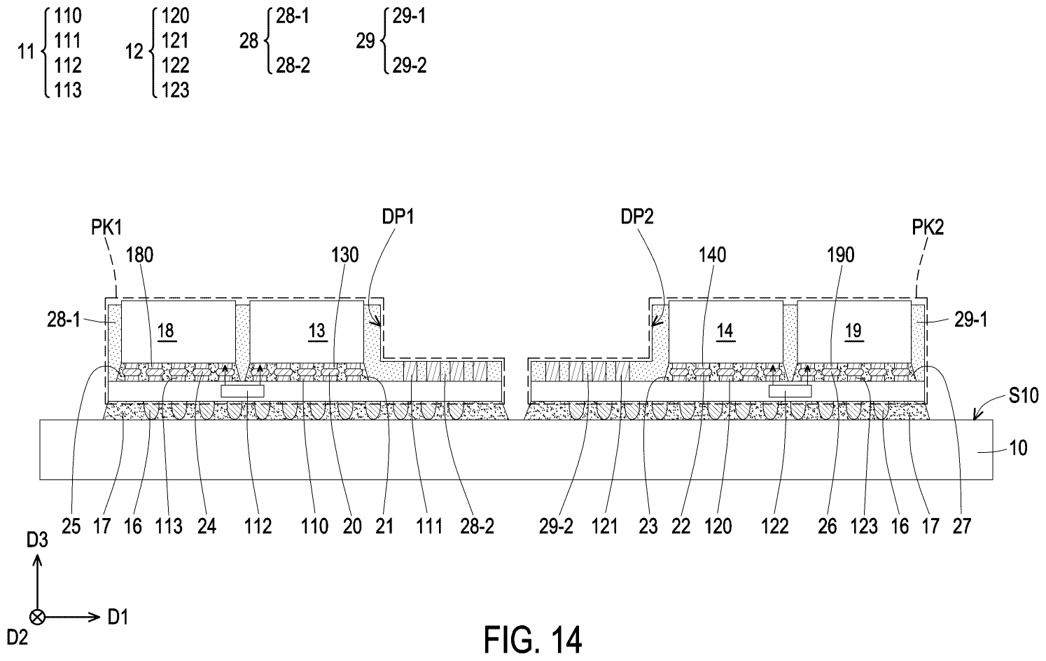

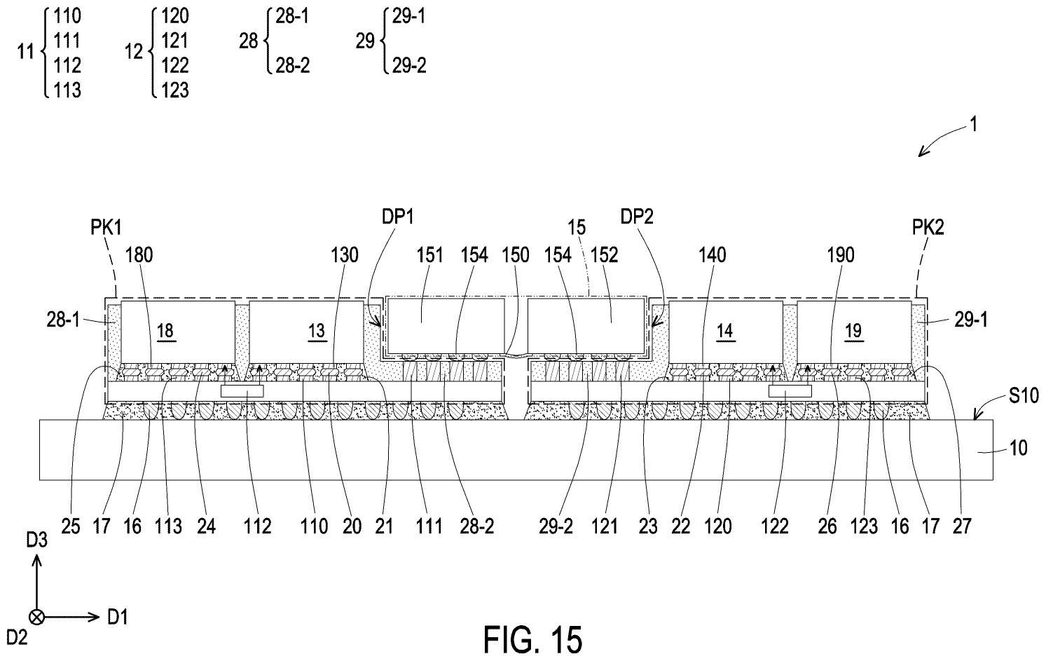

FIG. 1 is a schematic top view of a package structure according to some embodiments of the present disclosure. FIG. 2 is a schematic sectional view taken along line I-I′ in FIG. 1. FIG. 3 and FIG. 4 are two schematic sectional views illustrating two examples of a flexible interconnect structure in FIG. 2. FIG. 5 is a schematic top view of a package structure according to some embodiments of the present disclosure. FIG. 6 is a schematic top view of a package structure according to some embodiments of the present disclosure. FIG. 7 is a schematic sectional view of a package structure according to some embodiments of the present disclosure. FIG. 8 is a schematic sectional view of a package structure according to some embodiments of the present disclosure. FIG. 9 is a schematic top view of a package structure according to some embodiments of the present disclosure. FIG. 10 is a schematic top view of a package structure according to some embodiments of the present disclosure. FIG. 11 is a schematic sectional view taken along line II-II′ in FIG. 10. FIG. 12 is a schematic top view of a package structure according to some embodiments of the present disclosure. FIG. 13, FIG. 14 and FIG. 15 are schematic sectional views illustrating a manufacturing method of a package structure according to some embodiments of the present disclosure.

Referring to FIG. 1 and FIG. 2, a package structure 1 according to some embodiments of the present disclosure is provided. The package structure 1 includes a substrate 10, a first interposer 11, a second interposer 12, a first semiconductor die 13, a second semiconductor die 14 and a flexible interconnect structure 15. The first interposer 11 is bonded to the substrate 10. The second interposer 12 is bonded to the substrate 10 and spaced apart from the first interposer 11. The first semiconductor die 13 is bonded to the first interposer 11. The second semiconductor die 14 is bonded to the second interposer 12. The flexible interconnect structure 15 is bonded to the first interposer 11 and the second interposer 12.

Specifically, the substrate 10 may be a circuit substrate such as a motherboard, a printed circuit board, or the like. The first interposer 11 and the second interposer 12 may be bonded to the substrate 10 through a plurality of connectors 16. In some embodiments, a material of the plurality of connectors 16 includes copper, copper alloys, or other conductive materials, and the plurality of connectors 16 is formed by deposition, plating, or other suitable techniques. In some embodiments, the plurality of connectors 16 are prefabricated structures attached to contact pads (not shown) of the first interposer 11 and the second interposer 12. In some embodiments, the plurality of connectors 16 are solder balls, metal pillars, controlled collapse chip connection bumps, micro bumps, bumps formed via electroless nickel—electroless palladium—immersion gold technique (ENEPIG), combination thereof (e. g, a metal pillar with a solder ball attached), or the like.

In some embodiments, an underfill 17 is disposed between the substrate 10 and at least one of the first interposer 11 and the second interposer 12 to protect the plurality of connectors 16 against thermal or physical stresses and to secure the electrical connection of the substrate 10 with the at least one of the first interposer 11 and the second interposer 12. In some embodiments, the underfill 17 is formed by capillary underfill filling (CUF). A dispenser (not shown) may apply a filling material (not shown) along the perimeter of the at least one of the first interposer 11 and the second interposer 12. In some embodiments, a heating process is performed to let the filling material penetrate in the interstices defined by the plurality of connectors 16 between the substrate 10 and the at least one of the first interposer 11 and the second interposer 12 by capillarity. In some embodiments, a curing process is performed to consolidate the underfill 17.

In some embodiments, the first interposer 11 and the second interposer 12 are arranged along a first direction D1 that is parallel to a surface S10 of the substrate 10 bonded to the first interposer 11 and the second interposer 12. In some embodiments, the second interposer 12 is spaced apart from the first interposer 11 by a distance DT along the first direction D1. The size of the distance DT can be determined by the line spacing of the substrate 10 and is not limited herein.

The first interposer 11 may be a silicon interposer, an organic interposer, or the like. In some embodiments, the first interposer 11 includes elementary semiconductor materials such as silicon or germanium, compound semiconductor materials such as silicon carbide, gallium arsenide, indium arsenide, or indium phosphide or alloy semiconductor materials such as silicon germanium, silicon germanium carbide, gallium arsenide phosphide, or gallium indium phosphide. In some embodiments, the first interposer 11 includes silicon on insulator (SOI) or silicon-germanium on insulator (SGOI). In some embodiments, the first interposer 11 includes active elements (e.g., transistors or the like) formed therein. In some embodiments, the first interposer 11 includes passive elements (e.g., resistors, capacitors, inductors, or the like) formed therein. In some embodiments, the first interposer 11 includes a silicon wafer. In some embodiments, the first interposer 11 is a package substrate or ball grid array (BGA) substrate including one or more active elements, passive elements, or a combination thereof. In some embodiments, the first interposer 11 may be provided for dual-side electrical connection.

In some embodiments, the first interposer 11 includes a plurality of first bonding pads 110 bonded to the first semiconductor die 13 and a plurality of first conductors 111 bonded to the flexible interconnect structure 15. In some embodiments, materials of the plurality of first bonding pads 110 and the plurality of first conductors 111 include aluminum, copper, titanium, tungsten, other suitable metal, the alloys, other conductive materials, the combinations or the like. In some embodiments, in a top view, as shown in FIG. 1, the plurality of first conductors 111 are located outside an orthogonal projection P13 of the first semiconductor die 13 on the substrate 10. In some embodiments, as shown in FIG. 2, the plurality of first conductors 111 are thicker than the plurality of first bonding pads 110.

In some embodiments, the first interposer 11 also includes interconnection structures and/or redistribution layers (not shown) to connect various elements therein to form functional circuitry. In some embodiments, the interconnection structures includes a plurality of vias (not shown), a plurality of wires (not shown) and/or a plurality of bridge dies 112 (only one is shown in FIG. 2; not shown in the top view (FIG. 1)). In some embodiments, the first semiconductor die 13 and an adjacent semiconductor die (e.g., a third semiconductor die 18) are electrically connected by a corresponding bridge die 112 among the plurality of bridge dies 112. In some embodiments, the plurality of bridge dies 112 are local silicon interconnect (LSI) dies or the like.

The second interposer 12 may be a silicon interposer, an organic interposer, or the like. In some embodiments, the second interposer 12 includes elementary semiconductor materials such as silicon or germanium, compound semiconductor materials such as silicon carbide, gallium arsenide, indium arsenide, or indium phosphide or alloy semiconductor materials such as silicon germanium, silicon germanium carbide, gallium arsenide phosphide, or gallium indium phosphide. In some embodiments, the second interposer 12 includes silicon on insulator (SOI) or silicon-germanium on insulator (SGOI). In some embodiments, the second interposer 12 includes active elements (e.g., transistors or the like) formed therein. In some embodiments, the second interposer 12 includes passive elements (e.g., resistors, capacitors, inductors, or the like) formed therein. In some embodiments, the second interposer 12 includes a silicon wafer. In some embodiments, the second interposer 12 is a package substrate or ball grid array (BGA) substrate including one or more active elements, passive elements, or a combination thereof. In some embodiments, the second interposer 12 may be provided for dual-side electrical connection.

In some embodiments, the second interposer 12 includes a plurality of second bonding pads 120 bonded to the second semiconductor die 14 and a plurality of second conductors 121 bonded to the flexible interconnect structure 15. In some embodiments, materials of the plurality of second bonding pads 120 and the plurality of second conductors 121 include aluminum, copper, titanium, tungsten, other suitable metal, the alloys, other conductive materials, the combinations or the like. In some embodiments, in the top view, as shown in FIG. 1, the plurality of second conductors 121 are located outside an orthogonal projection P14 of the second semiconductor die 14 on the substrate 10. In some embodiments, as shown in FIG. 2, the plurality of second conductors 121 are thicker than the plurality of second bonding pads 120.

In some embodiments, the second interposer 12 also includes interconnection structures and/or redistribution layers (not shown) to connect various elements therein to form functional circuitry. In some embodiments, the interconnection structures includes a plurality of vias (not shown), a plurality of wires (not shown) and/or a plurality of bridge dies 122 (only one is shown in FIG. 2; not shown in the top view (FIG. 1)). In some embodiments, the second semiconductor die 14 and an adjacent semiconductor die (e.g., a fourth semiconductor die 19) are electrically connected by a corresponding bridge die 122 among the plurality of bridge dies 122. In some embodiments, the plurality of bridge dies 122 are local silicon interconnect (LSI) dies or the like.

The first semiconductor die 13 is bonded to the first interposer 11 through, for example, a plurality of connectors 20. Specifically, the first semiconductor die 13 includes a plurality of pads 130, and the plurality of pads 130 are bonded to the plurality of first bonding pads 110 of the first interposer 11 through the plurality of connectors 20. The plurality of connectors 20 may be made of a conductive material similar to those previously discussed with reference to the plurality of connectors 16, and will not be repeated here. The plurality of pads 130 may be made of a conductive material similar to those previously discussed with reference to the plurality of first bonding pads 110, and will not be repeated here. In some embodiments, an underfill 21 is disposed between the first interposer 11 and the first semiconductor die 13 to protect the plurality of connectors 20 against thermal or physical stresses and to secure the electrical connection of the first interposer 11 with the first semiconductor die 13. In some embodiments, the underfill 21 is made of a method and/or a material similar to those previously discussed with reference to the underfill 17, and will not be repeated here.

In some embodiments, the first semiconductor die 13 includes a logic die, such as a central processing unit (CPU) die, a graphic processing unit (GPU) die, a micro control unit (MCU) die, an input-output (I/O) die, a baseband (BB) die, an application processor (AP) die or the like. In some embodiments, the first semiconductor die 13 includes a memory die such as a high bandwidth memory die.

The second semiconductor die 14 is bonded to the second interposer 12 through, for example, a plurality of connectors 22. Specifically, the second semiconductor die 14 includes a plurality of pads 140, and the plurality of pads 140 are bonded to the plurality of second bonding pads 120 of the second interposer 12 through the plurality of connectors 22. The plurality of connectors 22 may be made of a conductive material similar to those previously discussed with reference to the plurality of connectors 16, and will not be repeated here. The plurality of pads 140 may be made of a conductive material similar to those previously discussed with reference to the plurality of first bonding pads 110, and will not be repeated here. In some embodiments, an underfill 23 is disposed between the second interposer 12 and the second semiconductor die 14 to protect the plurality of connectors 22 against thermal or physical stresses and to secure the electrical connection of the second interposer 12 with the second semiconductor die 14. In some embodiments, the underfill 23 is made of a method and/or a material similar to those previously discussed with reference to the underfill 17, and will not be repeated here.

In some embodiments, the second semiconductor die 14 includes a logic die, such as a central processing unit (CPU) die, a graphic processing unit (GPU) die, a micro control unit (MCU) die, an input-output (I/O) die, a baseband (BB) die, an application processor (AP) die or the like. In some embodiments, the second semiconductor die 14 includes a memory die such as a high bandwidth memory die. In some embodiments, the first semiconductor die 13 and the second semiconductor die 14 are the same type of dies or perform the same functions. In other embodiments, the first semiconductor die 13 and the second semiconductor die 14 are different types of dies or perform different functions.

The flexible interconnect structure 15 may be disposed on and in contact with a portion of the first interposer 11 and a portion of the second interposer 12. In some embodiments, in a top view, as shown in FIG. 1, the flexible interconnect structure 15 partially overlaps the first interposer 11 and the second interposer 12 and is separated from the first semiconductor die 13 and the second semiconductor die 14. Specifically, along a third direction D3 perpendicular to the substrate 10, the flexible interconnect structure 15 overlaps a portion of the first interposer 11 close to the second interposer 12 and overlaps a portion of the second interposer 12 close to the first interposer 11, and in the top view, as shown in FIG. 1, the flexible interconnect structure 15 is located outside the orthogonal projection P13 of the first semiconductor die 13 and the orthogonal projection P14 of the second semiconductor die 14. In some embodiments, in a sectional view, as shown in FIG. 2, the first interposer 11 and the second interposer 12 are located between the flexible interconnect structure 15 and the substrate 10.

In some embodiments, as shown in FIG. 3 or FIG. 4 (in which the flexible interconnect structure 15 is turned upside down for illustration purposes), the flexible interconnect structure 15 includes a first bridge die 151, a second bridge die 152, a flexible substrate 150, a plurality of conductive lines 153 and a plurality of conductive bumps 154. The first bridge die 151 and the second bridge die 152 are respectively adjacent to opposite ends of the flexible substrate 150. The plurality of conductive lines 153 are disposed on the flexible substrate 150 and electrically connect the first bridge die 151 to the second bridge die 152. The first bridge die 151 and the second bridge die 152 are respectively bonded to the first interposer 11 and the second interposer 12 through the plurality of conductive bumps 154, as shown in FIG. 2.

Specifically, the first bridge die 151 and the second bridge die 152 may be LSI bridge dies. In some embodiments, at least one of the first bridge die 151 and the second bridge die 152 includes an embedded capacitor C to filter the ripple in the circuit, thereby reducing signal distortion. In FIG. 3 or FIG. 4, the first bridge die 151 includes one embedded capacitor C, and the embedded capacitor C is electrically connected to at least one pad P151 among a plurality of pads P151 of the first bridge die 151. In addition, the second bridge die 152 includes one embedded capacitor C, and the embedded capacitor C is electrically connected to at least one pad P152 among a plurality of pads P152 of the second bridge die 152. In some embodiments, the embedded capacitor C is an embedded deep trench capacitor (eDTC), but not limited thereto. The plurality of pads P151 and the plurality of pads P152 may be made of a conductive material similar to those previously discussed with reference to the plurality of first bonding pads 110, and will not be repeated here.

The flexible substrate 150 may be a thin glass substrate, a plastic substrate or any other flexible substrate. The plurality of conductive lines 153 are formed at least on the flexible substrate 150 through, for example, a coating process, a photolithography process, a printing process, other suitable processes or combination of the above, and a material of the plurality of conductive lines 153 may include copper, gold, aluminum, the alloys, the combinations or the like. The plurality of conductive bumps 154 may be made of a conductive material similar to those previously discussed with reference to the plurality of connectors 16, and will not be repeated here.

In some embodiments, as shown in FIG. 3, the plurality of conductive lines 153 are located between the plurality of conductive bumps 154 and the flexible substrate 150, and the flexible interconnect structure 15 further includes a plurality of through vias 155 penetrating through the flexible substrate 150 and electrically connecting the plurality of conductive lines 153 to the first bridge die 151 and the second bridge die 152. Specifically, after the flexible substrate 150 is disposed on a side of the first bridge die 151 close to the plurality of pads P151 as well as on a side of the second bridge die 152 close to the plurality of pads P152, the plurality of through vias 155 are formed in the flexible substrate 150, and then the plurality of conductive lines 153 and the plurality of conductive bumps 154 are formed sequentially on the flexible substrate 150.

Alternatively, as shown in FIG. 4, the flexible substrate 150 is located between the plurality of conductive bumps 154 and the plurality of conductive lines 153, and the flexible interconnect structure 15 further includes a plurality of through vias 155 penetrating through the first bridge die 151 and the second bridge die 152 and electrically connecting the plurality of conductive lines 153 to the first bridge die 151 and the second bridge die 152. Specifically, the first bridge die 151 further includes a plurality of pads P151′ (only one is shown in FIG. 4), wherein the plurality of pads P151 and the plurality of pads P151′ are located on opposite sides of the first bridge die 151, and at least one pad P151′ is electrically connected to a corresponding pad P151 through at least one through via 155. Similarly, the second bridge die 152 further includes a plurality of pads P152′ (only one is shown in FIG. 4), wherein the plurality of pads P152 and the plurality of pads P152′ are located on opposite sides of the second bridge die 152, and at least one pad P152′ is electrically connected to a corresponding pad P152 through at least one through via 155. In addition, the plurality of conductive bumps 154 are formed on the plurality of pads P151 and the plurality of pads P152. After the flexible substrate 150 is disposed on a side of the first bridge die 151 close to the plurality of pads P151′ as well as on a side of the second bridge die 152 close to the plurality of pads P152′, the plurality of conductive lines 153 are formed on the flexible substrate 150 as well as on at least a portion of the plurality of pads P151′ and on at least a portion of the plurality of pads P152′.

According to different requirements, the package structure 1 may further include one or more elements. Optionally, the package structure 1 further includes a third semiconductor die 18 bonded to the first interposer 11 and adjacent to the first semiconductor die 13. The third semiconductor die 18 is bonded to the first interposer 11 through, for example, a plurality of connectors 24. Specifically, the third semiconductor die 18 includes a plurality of pads 180, and the plurality of pads 180 are bonded to a plurality of third bonding pads 113 of the first interposer 11 through the plurality of connectors 24. The plurality of connectors 24 may be made of a conductive material similar to those previously discussed with reference to the plurality of connectors 16, and will not be repeated here. The plurality of pads 180 and the plurality of third bonding pads 113 may be made of a conductive material similar to those previously discussed with reference to the plurality of first bonding pads 110, and will not be repeated here. In some embodiments, an underfill 25 is disposed between the first interposer 11 and the third semiconductor die 18 to protect the plurality of connectors 24 against thermal or physical stresses and to secure the electrical connection of the first interposer 11 with the third semiconductor die 18. In some embodiments, the underfill 25 is made of a method and/or a material similar to those previously discussed with reference to the underfill 17, and will not be repeated here.

In some embodiments, the third semiconductor die 18 includes a logic die or a memory die. In some embodiments, the first semiconductor die 13 is a logic die, and the third semiconductor die 18 is a memory die. In some embodiments, the number of the third semiconductor die 18 in the package structure 1 is plural. As shown in FIG. 1, the plurality of third semiconductor dies 18 may be arranged along a second direction D2 on a side the first semiconductor die 13 that is opposite to flexible interconnect structure 15. The second direction D2 is perpendicular to the first direction D1 and the third direction D3. However, the design parameters (e.g., quantity, relative arrangement relationship, size, etc.) of the third semiconductor dies 18, the first semiconductor die 13, the plurality of first conductors 111 and the flexible interconnect structure 15 may be modified according to needs and should not be limited to those shown in FIG. 1.

Optionally, the package structure 1 further includes a fourth semiconductor die 19 bonded to the second interposer 12 and adjacent to the second semiconductor die 14. The fourth semiconductor die 19 is bonded to the second interposer 12 through, for example, a plurality of connectors 26. Specifically, the fourth semiconductor die 19 includes a plurality of pads 190, and the plurality of pads 190 are bonded to a plurality of fourth bonding pads 123 of the second interposer 12 through the plurality of connectors 26. The plurality of connectors 26 may be made of a conductive material similar to those previously discussed with reference to the plurality of connectors 16, and will not be repeated here. The plurality of pads 190 and the plurality of fourth bonding pads 123 may be made of a conductive material similar to those previously discussed with reference to the plurality of first bonding pads 110, and will not be repeated here. In some embodiments, an underfill 27 is disposed between the second interposer 12 and the fourth semiconductor die 19 to protect the plurality of connectors 26 against thermal or physical stresses and to secure the electrical connection of the second interposer 12 with the fourth semiconductor die 19. In some embodiments, the underfill 27 is made of a method and/or a material similar to those previously discussed with reference to the underfill 17, and will not be repeated here.

In some embodiments, the fourth semiconductor die 19 includes a logic die or a memory die. In some embodiments, the second semiconductor die 14 is a logic die, and the fourth semiconductor die 19 is a memory die. In some embodiments, the number of the fourth semiconductor die 19 in the package structure 1 is plural. As shown in FIG. 1, the plurality of fourth semiconductor dies 19 may be arranged along the second direction D2 on a side the second semiconductor die 14 that is opposite to flexible interconnect structure 15. However, the design parameters (e.g., quantity, relative arrangement relationship, size, etc.) of the fourth semiconductor die 19, the second semiconductor die 14, the plurality of second conductors 121 and the flexible interconnect structure 15 may be modified according to needs and should not be limited to those shown in FIG. 1.

In some embodiments, the package structure 1 further includes a first encapsulant 28 and a second encapsulant 29. The first encapsulant 28 is disposed on the first interposer 11 and includes a first portion 28-1 and a second portion 28-2. The first portion 28-1 laterally encapsulates the first semiconductor die 13, namely, the first portion 28-1 is in contact with side surfaces of the first semiconductor die 13. In the embodiments in which the plurality of third semiconductor dies 18 are included, the first portion 28-1 also laterally encapsulates the plurality of third semiconductor dies 18. The second portion 28-2 is connected to the first portion 28-1 and located between the flexible interconnect structure 15 and the first interposer 11, wherein the plurality of first conductors 111 penetrate through the second portion 28-2 to electrically connect the flexible interconnect structure 15. Specifically, the second portion 28-2 is a portion of the first encapsulant 28 that is thinned to reveal the plurality of first conductors 111 and/or to accommodate a portion of the flexible interconnect structure 15. In some embodiments, as shown in FIG. 2, the second portion 28-2 is thinner than the first portion 28-1. The second encapsulant 29 is disposed on the second interposer 12 and includes a third portion 29-1 and a fourth portion 29-2. The third portion 29-1 laterally encapsulates the second semiconductor die 14. In the embodiments in which the plurality of fourth semiconductor dies 19 are included, the third portion 29-1 also laterally encapsulates the plurality of fourth semiconductor dies 19. The fourth portion 29-2 is connected to the third portion 29-1 and located between the flexible interconnect structure 15 and the second interposer 12, wherein the plurality of second conductors 121 penetrate through the fourth portion 29-2 to electrically connect the flexible interconnect structure 15. Specifically, the fourth portion 29-2 is a portion of the second encapsulant 29 that is thinned to reveal the plurality of second conductors 121 and/or to accommodate another portion of the flexible interconnect structure 15. In some embodiments, as shown in FIG. 2, the fourth portion 29-2 is thinner than the third portion 29-1.

In some embodiments, a package structure (e.g., the package structure 1 shown in FIG. 1 and FIG. 2) includes a substrate (e.g., the substrate 10 shown in FIG. 1 and FIG. 2), a first package PK1, a second package PK2 and a flexible interconnect structure (e.g., the flexible interconnect structure 15 shown in FIG. 1 and FIG. 2). The first package PK1 is bonded to the substrate 10. The second package PK2 is bonded to the substrate 10 and adjacent to the first package PK1, wherein the first package PK1 has a first depression DP1 adjacent to the second package PK2, and the second package PK2 has a second depression DP2 adjacent to the first depression DP1. The flexible interconnect structure 15 is located in the first depression DP1 and the second depression DP2 and electrically connects the first package PK1 to the second package PK2.

In some embodiments, in a sectional view, as shown in FIG. 2, a length L15 of the flexible interconnect structure 15 is larger than a total length of the first depression DP1 and the second depression DP2. The total length of the first depression DP1 and the second depression DP2 is the sum of a length LDP1 of the first depression DP1 and a length LDP2 of the second depression DP2. In other words, L15>(LDP1+LDP2).

In some embodiments, as shown in FIG. 2, the first bridge die 151 and the second bridge die 152 are respectively bonded to the first package PK1 and the second package PK2 through the plurality of conductive bumps 154.

In some embodiments, the first package PK1 includes the first interposer 11, the first semiconductor die 13 and the first encapsulant 28, wherein in the sectional view, as shown in FIG. 2, the first depression DP1 is on a side of the first encapsulant 28 adjacent to the second package PK2. Specifically, the first depression DP1 is a portion of the first encapsulant 28 that is removed to reveal the plurality of first conductors 111 and/or to accommodate a portion of the flexible interconnect structure 15. In some embodiments, the first package PK1 further includes the elements that are encapsulated by the first encapsulant 28. For example, as shown in FIG. 2, the first package PK1 may further include the plurality of connectors 20, the underfill 21, the plurality of third semiconductor dies 18, the plurality of connectors 24 and the underfill 25.

In some embodiments, the second package PK2 includes the second interposer 12, the second semiconductor die 14 and the second encapsulant 29, wherein in the sectional view, as shown in FIG. 2, the second depression DP2 is on a side of the second encapsulant 29 adjacent to the first package PK1. Specifically, the second depression DP2 is a portion of the second encapsulant 29 that is removed to reveal the plurality of second conductors 121 and/or to accommodate another portion of the flexible interconnect structure 15. In some embodiments, the second package PK2 further includes the elements that are encapsulated by the second encapsulant 29. For example, as shown in FIG. 2, the second package PK2 may further include the plurality of connectors 22, the underfill 23, the plurality of fourth semiconductor dies 19, the plurality of connectors 26 and the underfill 27.

In the embodiments, the interconnection between packages (e.g., the first package PK1 and the second package PK2) can gain more space and/or degrees of freedom by disposing the interconnect structure (e.g., the flexible interconnect structure 15) between or above adjacent packages. In addition, the flexibility of the flexible substrate 150 allows the position and/or height of each bridge die (e.g., each of the first bridge die 151 and the second bridge die 152) to be independently adjusted based on the conditions of the bonding surfaces of adjacent packages. Therefore, utilizing the flexible interconnect structure 15 to bond adjacent packages can help reduce bonding difficulty or bonding failure rates owning to the bonding surfaces of adjacent packages are uneven or have different heights/levels, and/or improve yield. At least one of the bridge dies in the flexible interconnect structure can include high capacitance (e.g., each of the bridge dies includes an embedded deep trench capacitor) to filter the ripple in the circuit, thereby reducing signal distortion. The flexible interconnect structure can be bonded to the adjacent packages through an active alignment assembly process, during which electrical signals are provided while simultaneously measuring the output signal repeatedly to confirm whether there is electrical conduction between the flexible interconnect structure and the bonded packages, thereby the bonding of the flexible interconnect structure to the adjacent packages can be confirmed in time, and repairs can be made immediately in case of bonding failure.

Referring to FIG. 5, a package structure 1A according to some embodiments of the present disclosure is provided. In the package structure 1A, the number of the third semiconductor dies 18 is four, and the number of the fourth semiconductor dies 19 is four. In the first package PK1, two of the plurality of third semiconductor dies 18 is on the left side of the first semiconductor die 13, while the other two of the plurality of third semiconductor dies 18 is on the right side of the first semiconductor die 13. In the second package PK2, two of the plurality of fourth semiconductor dies 19 is on the left side of the second semiconductor die 14, while the other two of the plurality of fourth semiconductor dies 19 is on the right side of the second semiconductor die 14. In the top view, as shown in FIG. 5, the flexible interconnect structure 15 is surrounded by the first semiconductor die 13, the second semiconductor die 14, two of the plurality of third semiconductor dies 18 and two of the plurality of fourth semiconductor dies 19.

In some embodiments, although not shown, the package structure 1A includes at least one dummy die. The dummy die may be made of a bulk silicon, but not limited thereto. In the top view, at least one dummy die is located between two of the plurality of third semiconductor dies 18 on the left side of the first semiconductor die 13 and/or at least one dummy die is located between two of the plurality of fourth semiconductor dies 19 on the right side of the second semiconductor die 14.

Referring to FIG. 6, a package structure 1B according to some embodiments of the present disclosure is provided. In the package structure 1B, the first package PK1 and the second package PK2 are arranged along the second direction D2, and the flexible interconnect structure 15 connects the first package PK1 and the second package PK2 along the second direction D2.

It should be understood that the top views described above are merely examples and are not intended to be limiting. The design parameters (e.g., quantity, relative arrangement relationship, size, etc.) of the packages, the interposers, the semiconductor dies, the conductors, the encapsulants and the flexible interconnect structure may be modified according to needs.

Referring to FIG. 7, a package structure 1C according to some embodiments of the present disclosure is provided. In the package structure 1C, edges of the first interposer 11 and the second interposer 12 are warped due to thermal stress. The warpage of edges of the interposer (e.g., the first interposer 11 or the second interposer 12) causes the heights of the plurality of conductors (e.g., the plurality of first conductors 111 or the plurality of second conductors 121) located at the edge of the interposer to be inconsistent. For example, the plurality of conductors are taller as they are closer to the edge. When forming the depression (e.g., the first depression DP1 or the second depression DP2) to reveal bonding surfaces of the plurality of conductors, the tops of the higher conductors may be unintentionally removed in order to reveal the bonding surfaces of the lower conductors. By making the conductors thicker than the pads (e.g., the plurality of first bonding pads 110 or the plurality of second bonding pads 120), the chance of complete removal of the higher conductors when forming the depression is reduced.

In some embodiments, the bonding surfaces of the first package PK1 and the second package PK2 are uneven or have different heights/levels due to factors such as materials, process parameters, process errors, etc. Since the flexibility of the flexible substrate 150 allows the position and/or height of each bridge die (e.g., each of the first bridge die 151 and the second bridge die 152) to be independently adjusted based on the conditions of the bonding surfaces of adjacent packages, the bonding difficulty or bonding failure rates can be reduced, and/or the bonding yield can be improved.

Referring to FIG. 8, a package structure 1D according to some embodiments of the present disclosure is provided. The package structure 1D further includes another flexible interconnect structure (e.g., a flexible interconnect structure 15A) bonded to the first semiconductor die 13 and the third semiconductor die 18, wherein the first semiconductor die 13 and the third semiconductor die 18 are located between the another flexible interconnect structure (e.g., the flexible interconnect structure 15A) and the first interposer 11. The flexible interconnect structure 15A may have a construction similar to those previously discussed with reference to the flexible interconnect structure 15 (e.g., see FIG. 3 or FIG. 4), and will not be repeated here. In the embodiments, the flexible interconnect structure 15A is configured to provide a signal transmission path between the first semiconductor die 13 and the third semiconductor die 18, and the bridge die 112 (e.g., see FIG. 7) within the first interposer 11 is omitted. However, in other embodiments, both of the flexible interconnect structure 15A and the bridge die 112 may be included to provide multiple signal transmission paths between the first semiconductor die 13 and the third semiconductor die 18.

In the embodiments, the interconnection between semiconductor dies (e.g., the first semiconductor die 13 and the third semiconductor die 18) can gain more space and/or degrees of freedom by disposing the interconnect structure (e.g., the flexible interconnect structure 15A) above adjacent semiconductor dies. In addition, the flexibility of the flexible substrate of the flexible interconnect structure 15A allows the position and/or height of each bridge die to be independently adjusted based on the conditions of the bonding surfaces of adjacent semiconductor dies (in FIG. 8, the bonding surfaces of the first semiconductor die 13 and the third semiconductor die 18 are uneven or have different heights/levels due to factors such as materials, process parameters, process errors, etc.) Therefore, utilizing the flexible interconnect structure 15A to bond adjacent semiconductor dies can help reduce bonding difficulty or bonding failure rates owning to the bonding surfaces of adjacent packages are uneven or have different heights/levels, and/or improve yield. At least one of the bridge dies in the flexible interconnect structure 15A can include high capacitance (e.g., each of the bridge dies includes an embedded deep trench capacitor) to filter the ripple in the circuit, thereby reducing signal distortion. The flexible interconnect structure 15A can be bonded to the adjacent semiconductor dies through the active alignment assembly process so that the bonding of the flexible interconnect structure 15A to the adjacent semiconductor dies can be confirmed in time, and repairs can be made immediately in case of bonding failure.

Referring to FIG. 9, a package structure 1E according to some embodiments of the present disclosure is provided. The package structure 1E includes two flexible interconnect structures 15A, and each of the two flexible interconnect structures 15A is connected between the first semiconductor die 13 and a corresponding third semiconductor die 18. In other embodiments, although not shown, more than one flexible interconnect structure 15A and more than one bridge dies (e.g., the bridge die 112 or the bridge die 122 in FIG. 7) within the interposer (e.g., the first interposer 11 or the second interposer 12) may be included to provide multiple signal transmission paths between two adjacent semiconductor dies (e.g., the first semiconductor die 13 and an adjacent third semiconductor die 18 and/or a second semiconductor die 14 and an adjacent fourth semiconductor die 19).

Referring to FIG. 10 and FIG. 11, a package structure IF according to some embodiments of the present disclosure is provided. In the package structure 1F, the number of the packages is one. The first package PK1 is illustrated as an example. In the package structure IF, the flexible interconnect structure 15 described above is not needed. Correspondingly, the first package PK1 does not include the first depression DP1, the first interposer 11F does not include the plurality of first conductors 111, and there's no need to remove a portion of the first encapsulant 28F to reveal the plurality of first conductors 111. In addition, at least one of the flexible interconnect structure 15A and the bridge die 112 is electrically connected between the first semiconductor die 13 and an adjacent third semiconductor die 18.

Referring to FIG. 12, a package structure 1G according to some embodiments of the present disclosure is provided. In the package structure 1G, the number of the first semiconductor dies 13 is two, and the two first semiconductor dies 13 are arranged along the second direction D2. In addition, the number of the flexible interconnect structures 15A is two, wherein one of the two flexible interconnect structures 15A is bonded on and electrically connected between the first semiconductor die 13 and an adjacent third semiconductor die 18, and the other one of the two flexible interconnect structures 15A is bonded on and electrically connected between the two first semiconductor dies 13.

Referring to FIG. 13 to FIG. 15, a manufacturing method of a package structure (e.g., the package structure 1 in FIG. 2) according to some embodiments of the present disclosure is provided. The manufacturing method of the package structure 1 includes: bonding a first package PK1 to a substrate 10, as shown in FIG. 13; bonding a second package PK2 to the substrate 10, as shown in FIG. 13; patterning the first package PK1 to form a first depression DP1 that reveals at least one first conductor 111, as shown in FIG. 14; patterning the second package PK2 to form a second depression DP2 that reveals at least one second conductor 121, as shown in FIG. 14; and bonding a flexible interconnect structure 15 to the at least one first conductor 111 and the at least one second conductor 121, as shown in FIG. 15.

In some embodiments, as shown in FIG. 13, bonding the first package PK1 to the substrate 10 includes: bonding a first interposer 11 to the substrate 10; bonding a first semiconductor die 13 to the first interposer 11; and encapsulating the first semiconductor die 13 and the at least one first conductor 111. Encapsulating the first semiconductor die 13 and the at least one first conductor 111 is subsequent to bonding the first semiconductor die 13 to the first interposer 11. On the other hand, the order of bonding the first interposer 11 to the substrate 10 and bonding the first semiconductor die 13 to the first interposer 11 is not limited. In other words, bonding the first interposer 11 to the substrate 10 may be prior to or subsequent to bonding the first semiconductor die 13 to the first interposer 11.

Optionally, as shown in FIG. 13, bonding the first package PK1 to the substrate 10 may further include bonding a third semiconductor die 18 to the first interposer 11, and the third semiconductor die 18 may be encapsulated simultaneously with the first semiconductor die 13 and the at least one first conductor 111.

In some embodiments, as shown in FIG. 13, bonding the second package PK2 to the substrate 10 includes: bonding a second interposer 12 to the substrate 10; bonding a second semiconductor die 14 to the second interposer 12; and encapsulating the second semiconductor die 14 and the at least one second conductor 121. Encapsulating the second semiconductor die 14 and the at least one second conductor 121 is subsequent to bonding the second semiconductor die 14 to the second interposer 12. On the other hand, the order of bonding the second interposer 12 to the substrate 10 and bonding the second semiconductor die 14 to the second interposer 12 is not limited. In other words, bonding the second interposer 12 to the substrate 10 may be prior to or subsequent to bonding the second semiconductor die 14 to the second interposer 12.

Optionally, as shown in FIG. 13, bonding the second package PK2 to the substrate 10 may further include bonding a fourth semiconductor die 19 to the second interposer 12, and the fourth semiconductor die 19 may be encapsulated simultaneously with the second semiconductor die 14 and the at least one second conductor 121.

In some embodiments, as shown in FIG. 14, patterning the first package PK1 to form the first depression DP1 includes removing a portion of the first encapsulant 28 covering the at least one first conductor 111. Similarly, patterning the second package PK2 to form the second depression DP2 includes removing a portion of the second encapsulant 29 covering the at least one second conductor 121. For example, laser trimming, laser grooving or other suitable methods may be adopted to remove the portion of the first encapsulant 28 and the portion of the second encapsulant 29.

In some embodiments, as shown in FIG. 15, bonding the flexible interconnect structure 15 to the at least one first conductor 111 and the at least one second conductor 121 includes bonding a first bridge die 151 and a second bridge die 152 respectively to the at least one first conductor 111 and the at least one second conductor 121 through a plurality of conductive bumps 154, wherein a flexible substrate 150 on which a plurality of conductive lines 153 (see FIG. 3 or FIG. 4) electrically connected to the first bridge die 151 and the second bridge die 152 are disposed is connected between the first bridge die 151 and the second bridge die 152.

Based on the above discussions, it can be seen that the present disclosure offers various advantages. It is understood, however, that not all advantages are necessarily discussed herein, and other embodiments may offer different advantages, and that no particular advantage is required for all embodiments.

According to some embodiments, a package structure includes a substrate, a first interposer, a second interposer, a first semiconductor die, a second semiconductor die and a flexible interconnect structure. The first interposer is bonded to the substrate. The second interposer is bonded to the substrate and spaced apart from the first interposer. The first semiconductor die is bonded to the first interposer. The second semiconductor die is bonded to the second interposer. The flexible interconnect structure is bonded to the first interposer and the second interposer. In some embodiments, in a top view, the flexible interconnect structure partially overlaps the first interposer and the second interposer and is separated from the first semiconductor die and the second semiconductor die. In some embodiments, in a sectional view, the first interposer and the second interposer are located between the flexible interconnect structure and the substrate. In some embodiments, the first interposer includes a plurality of first bonding pads bonded to the first semiconductor die and a plurality of first conductors bonded to the flexible interconnect structure. The second interposer includes a plurality of second bonding pads bonded to the second semiconductor die and a plurality of second conductors bonded to the flexible interconnect structure. In a top view, the plurality of first conductors are located outside an orthogonal projection of the first semiconductor die on the substrate. In the top view, the plurality of second conductors are located outside an orthogonal projection of the second semiconductor die on the substrate. In some embodiments, the package structure further includes a first encapsulant and a second encapsulant. The first encapsulant is disposed on the first interposer and includes a first portion laterally encapsulating the first semiconductor die and a second portion connected to the first portion and located between the flexible interconnect structure and the first interposer, wherein the plurality of first conductors penetrate through the second portion to electrically connect the flexible interconnect structure. The second encapsulant is disposed on the second interposer and includes a third portion laterally encapsulating the second semiconductor die and a fourth portion connected to the third portion and located between the flexible interconnect structure and the second interposer, wherein the plurality of second conductors penetrate through the fourth portion to electrically connect the flexible interconnect structure. In some embodiments, the second portion is thinner than the first portion, the plurality of first conductors are thicker than the plurality of first bonding pads, the fourth portion is thinner than the third portion, and the plurality of second conductors are thicker than the plurality of second bonding pads. In some embodiments, the flexible interconnect structure includes a first bridge die, a second bridge die, a flexible substrate, a plurality of conductive lines and a plurality of conductive bumps. The first bridge die and the second bridge die are respectively adjacent to opposite ends of the flexible substrate. The plurality of conductive lines are disposed on the flexible substrate and electrically connect the first bridge die to the second bridge die. The first bridge die and the second bridge die are respectively bonded to the first interposer and the second interposer through the plurality of conductive bumps. In some embodiments, the plurality of conductive lines are located between the plurality of conductive bumps and the flexible substrate, and the flexible interconnect structure further includes a plurality of through vias penetrating through the flexible substrate and electrically connecting the plurality of conductive lines to the first bridge die and the second bridge die. In some embodiments, the flexible substrate is located between the plurality of conductive bumps and the plurality of conductive lines, and the flexible interconnect structure further includes a plurality of through vias penetrating through the first bridge die and the second bridge die and electrically connecting the plurality of conductive lines to the first bridge die and the second bridge die. In some embodiments, at least one of the first bridge die and the second bridge die includes an embedded capacitor. In some embodiments, the package structure further includes a third semiconductor die bonded to the first interposer and adjacent to the first semiconductor die and another flexible interconnect structure bonded to the first semiconductor die and the third semiconductor die, wherein the first semiconductor die and the third semiconductor die are located between the another flexible interconnect structure and the first interposer.

According to some embodiments, a package structure includes a substrate, a first package, a second package and a flexible interconnect structure. The first package is bonded to the substrate. The second package is bonded to the substrate and adjacent to the first package, wherein the first package has a first depression adjacent to the second package, and the second package has a second depression adjacent to the first depression. The flexible interconnect structure is located in the first depression and the second depression and electrically connects the first package to the second package. In some embodiments, in a sectional view, a length of the flexible interconnect structure is larger than a total length of the first depression and the second depression. In some embodiments, the flexible interconnect structure includes a first bridge die, a second bridge die, a flexible substrate, a plurality of conductive lines and a plurality of conductive bumps. The first bridge die and the second bridge die are respectively adjacent to opposite ends of the flexible substrate. The plurality of conductive lines are disposed on the flexible substrate and electrically connect the first bridge die to the second bridge die. The first bridge die and the second bridge die are respectively bonded to the first package and the second package through the plurality of conductive bumps. In some embodiments, at least one of the first bridge die and the second bridge die includes an embedded capacitor. In some embodiments, the first package includes a first interposer bonded to the substrate, a first semiconductor die bonded to the first interposer and a first encapsulant disposed on the first interposer and laterally encapsulating the first semiconductor die, wherein in a sectional view, the first depression is on a side of the first encapsulant adjacent to the second package. The second package includes a second interposer bonded to the substrate, a second semiconductor die bonded to the second interposer and a second encapsulant disposed on the second interposer and laterally encapsulating the second semiconductor die, wherein in the sectional view, the second depression is on a side of the second encapsulant adjacent to the first package.

According to some embodiments, a manufacturing method of a package structure includes: bonding a first package to a substrate; bonding a second package to the substrate; patterning the first package to form a first depression that reveals at least one first conductor; patterning the second package to form a second depression that reveals at least one second conductor; and bonding a flexible interconnect structure to the at least one first conductor and the at least one second conductor. In some embodiments, bonding the first package to the substrate includes: bonding a first interposer to the substrate; bonding a first semiconductor die to the first interposer; and encapsulating the first semiconductor die and the at least one first conductor. In some embodiments, bonding the second package to the substrate includes: bonding a second interposer to the substrate; bonding a second semiconductor die to the second interposer; and encapsulating the second semiconductor die and the at least one second conductor. In some embodiments, bonding the flexible interconnect structure to the at least one first conductor and the at least one second conductor includes: bonding a first bridge die and a second bridge die respectively to the at least one first conductor and the at least one second conductor through a plurality of conductive bumps, wherein a flexible substrate on which a plurality of conductive lines electrically connected to the first bridge die and the second bridge die are disposed is connected between the first bridge die and the second bridge die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a substrate;
a first interposer bonded to the substrate;
a second interposer bonded to the substrate and spaced apart from the first interposer;
a first semiconductor die bonded to the first interposer;
a second semiconductor die bonded to the second interposer; and
a flexible interconnect structure bonded to the first interposer and the second interposer.

2. The package structure as claimed in claim 1, wherein in a top view, the flexible interconnect structure partially overlaps the first interposer and the second interposer and is separated from the first semiconductor die and the second semiconductor die.

3. The package structure as claimed in claim 1, wherein in a sectional view, the first interposer and the second interposer are located between the flexible interconnect structure and the substrate.

4. The package structure as claimed in claim 1, wherein:
the first interposer comprises:
a plurality of first bonding pads bonded to the first semiconductor die; and
a plurality of first conductors bonded to the flexible interconnect structure, the second interposer comprises:
a plurality of second bonding pads bonded to the second semiconductor die; and
a plurality of second conductors bonded to the flexible interconnect structure,
in a top view, the plurality of first conductors are located outside an orthogonal projection of the first semiconductor die on the substrate, and
in the top view, the plurality of second conductors are located outside an orthogonal projection of the second semiconductor die on the substrate.

5. The package structure as claimed in claim 4, further comprising:
a first encapsulant disposed on the first interposer and comprising:
a first portion laterally encapsulating the first semiconductor die; and
a second portion connected to the first portion and located between the flexible interconnect structure and the first interposer, wherein the plurality of first conductors penetrate through the second portion to electrically connect the flexible interconnect structure; and
a second encapsulant disposed on the second interposer and comprising:
a third portion laterally encapsulating the second semiconductor die; and
a fourth portion connected to the third portion and located between the flexible interconnect structure and the second interposer, wherein the plurality of second conductors penetrate through the fourth portion to electrically connect the flexible interconnect structure.

6. The package structure as claimed in claim 5, wherein:
the second portion is thinner than the first portion,
the plurality of first conductors are thicker than the plurality of first bonding pads,
the fourth portion is thinner than the third portion, and
the plurality of second conductors are thicker than the plurality of second bonding pads.

7. The package structure as claimed in claim 1, wherein the flexible interconnect structure comprises:
a first bridge die;
a second bridge die;
a flexible substrate, wherein the first bridge die and the second bridge die are respectively adjacent to opposite ends of the flexible substrate;
a plurality of conductive lines disposed on the flexible substrate and electrically connecting the first bridge die to the second bridge die; and
a plurality of conductive bumps, wherein the first bridge die and the second bridge die are respectively bonded to the first interposer and the second interposer through the plurality of conductive bumps.

8. The package structure as claimed in claim 7, wherein:
the plurality of conductive lines are located between the plurality of conductive bumps and the flexible substrate, and
the flexible interconnect structure further comprises a plurality of through vias penetrating through the flexible substrate and electrically connecting the plurality of conductive lines to the first bridge die and the second bridge die.

9. The package structure as claimed in claim 7, wherein:
the flexible substrate is located between the plurality of conductive bumps and the plurality of conductive lines, and
the flexible interconnect structure further comprises a plurality of through vias penetrating through the first bridge die and the second bridge die and electrically connecting the plurality of conductive lines to the first bridge die and the second bridge die.

10. The package structure as claimed in claim 7, wherein at least one of the first bridge die and the second bridge die comprises an embedded capacitor.

11. The package structure as claimed in claim 1, further comprising:
a third semiconductor die bonded to the first interposer and adjacent to the first semiconductor die; and
another flexible interconnect structure bonded to the first semiconductor die and the third semiconductor die, wherein the first semiconductor die and the third semiconductor die are located between the another flexible interconnect structure and the first interposer.

12. A package structure, comprising:
a substrate;
a first package bonded to the substrate;
a second package bonded to the substrate and adjacent to the first package, wherein the first package has a first depression adjacent to the second package, and the second package has a second depression adjacent to the first depression; and
a flexible interconnect structure located in the first depression and the second depression and electrically connecting the first package to the second package.

13. The package structure as claimed in claim 12, wherein in a sectional view, a length of the flexible interconnect structure is larger than a total length of the first depression and the second depression.

14. The package structure as claimed in claim 12, wherein the flexible interconnect structure comprises:
a first bridge die;
a second bridge die;
a flexible substrate, wherein the first bridge die and the second bridge die are respectively adjacent to opposite ends of the flexible substrate;
a plurality of conductive lines disposed on the flexible substrate and electrically connecting the first bridge die to the second bridge die; and
a plurality of conductive bumps, wherein the first bridge die and the second bridge die are respectively bonded to the first package and the second package through the plurality of conductive bumps.

15. The package structure as claimed in claim 14, wherein at least one of the first bridge die and the second bridge die comprises an embedded capacitor.

16. The package structure as claimed in claim 12, wherein:
the first package comprises:
a first interposer bonded to the substrate;
a first semiconductor die bonded to the first interposer; and
a first encapsulant disposed on the first interposer and laterally encapsulating the first semiconductor die, wherein in a sectional view, the first depression is on a side of the first encapsulant adjacent to the second package,
the second package comprises:
a second interposer bonded to the substrate;
a second semiconductor die bonded to the second interposer; and
a second encapsulant disposed on the second interposer and laterally encapsulating the second semiconductor die, wherein in the sectional view, the second depression is on a side of the second encapsulant adjacent to the first package.

17. A manufacturing method of a package structure, comprising:
bonding a first package to a substrate;
bonding a second package to the substrate;
patterning the first package to form a first depression that reveals at least one first conductor;
patterning the second package to form a second depression that reveals at least one second conductor; and
bonding a flexible interconnect structure to the at least one first conductor and the at least one second conductor.

18. The manufacturing method of the package structure as claimed in claim 17, wherein bonding the first package to the substrate comprises:
bonding a first interposer to the substrate;
bonding a first semiconductor die to the first interposer; and
encapsulating the first semiconductor die and the at least one first conductor.

19. The manufacturing method of the package structure as claimed in claim 17, wherein bonding the second package to the substrate comprises:
bonding a second interposer to the substrate;
bonding a second semiconductor die to the second interposer; and
encapsulating the second semiconductor die and the at least one second conductor.

20. The manufacturing method of the package structure as claimed in claim 17, wherein bonding the flexible interconnect structure to the at least one first conductor and the at least one second conductor comprises:
bonding a first bridge die and a second bridge die respectively to the at least one first conductor and the at least one second conductor through a plurality of conductive bumps, wherein a flexible substrate on which a plurality of conductive lines electrically connected to the first bridge die and the second bridge die are disposed is connected between the first bridge die and the second bridge die.
